(19) United States
(12) Patent Application Publication
(10) Pub. No.: US 2026/0164674 A1
(43) Pub. Date: Jun. 11, 2026

(54) SEMICONDUCTOR DEVICE INCLUDING RESISTIVE MEMORY CELL AND CELL CONTROL TRANSISTOR CONNECTED TO RESISTIVE MEMORY CELL

(71) Applicant: SK hynix Inc., Icheon-si (KR)

(72) Inventor: Jae Yeon LEE, Icheon-si (KR)

(21) Appl. No.: 19/232,763

(22) Filed: Jun. 9, 2025

(30) Foreign Application Priority Data
Sep. 24, 2024 (KR) 10-2024-0129347

(51) Int. Cl. H10B 63/00

(52) U.S. Cl. CPC H10B 63/30

(57) ABSTRACT

A semiconductor device according to an embodiment includes a cell control transistor, a resistive memory cell, and a bit line that are disposed on a substrate and coupled to one another. The resistive memory cell includes a cell selection transistor disposed to be spaced apart from the cell control transistor on the substrate, and a variable resistance element electrically connected to a drain electrode of the cell selection transistor. A source electrode of the cell control transistor and a source electrode of the cell selection transistor are electrically connected to the bit line in common.

### CROSS-REFERENCE TO RELATED APPLICATION

The present application claims priority under 35 U.S.C § 119(a) to Korean Application No. 10-2024-0129347, filed in the Korean Intellectual Property Office on Sep. 24, 2024, the entire contents of which are incorporated herein by reference.

### BACKGROUND

### 1. Technical Field

The present disclosure generally relates to a semiconductor device including a resistive memory cell.

### 2. Related Art

In general, a resistance change material refers to a material whose electrical resistance changes when an external stimulus such as heat, current, voltage, or light is applied. The resistance change material can maintain its altered electrical resistance even after the external stimulus is removed. A resistance change memory device is a product that utilizes these electrical characteristics of a resistance change material to store signal information.

The electrical resistance of a memory layer of the resistance change memory device switches between a low resistance state and a high resistance state by a set operation and a reset operation. The resistance change memory device can have a low resistance state and a high resistance state as signal information that are distinguishable from each other. Depending on the factor or stimulus causing the switching operation, the resistance change memory device can be classified into a resistive memory (resistive RAM) device, a phase change memory (phase change RAM) device, a magnetic memory (magnetic RAM) device, etc. Among the resistance change memory devices, a resistive memory (resistive RAM) device can implement varying different resistance states by generating or blocking a low-resistance electrical path within the resistance change layer using a voltage or current applied to both ends of the resistance change layer.

### SUMMARY

A semiconductor device according to an embodiment of the present disclosure includes a cell control transistor, a resistive memory cell, and a bit line that are disposed on a substrate and coupled to one another. The resistive memory cell includes a cell selection transistor disposed to be spaced apart from the cell control transistor on the substrate, and a variable resistance element electrically connected to a drain electrode of the cell selection transistor. A source electrode of the cell control transistor and a source electrode of the cell selection transistor are electrically connected to the bit line in common.

A semiconductor device according to an embodiment of the present disclosure includes a cell control transistor and a plurality of resistive memory cells that share a bit line. The cell control transistor may include a control source region and a control drain region that are disposed in the substrate, and a control gate electrode layer disposed on the substrate between the control source region and the control drain region. Each of the plurality of resistive memory cells may include a cell selection transistor including a cell source region and a cell drain region that are disposed in the substrate, and a cell gate electrode layer disposed on the substrate between the cell source region and the cell drain region, and a variable resistance structure electrically connected to the cell drain region of the cell selection transistor. The control source region and the cell source region may be electrically connected to the bit line in common.

### BRIEF DESCRIPTION OF THE DRAWINGS

FIG. 1 is a circuit diagram of a semiconductor device according to an embodiment of the present disclosure.

FIG. 2 is a schematic plan view illustrating a semiconductor device according to an embodiment of the present disclosure.

FIG. 3 is a diagram illustrating a plan view of FIG. 2 with a source line, a bit line, and a variable resistance element removed for convenience of illustration.

FIG. 4A is a schematic cross-sectional view illustrating a resistive memory cell of a semiconductor device according to an embodiment of the present disclosure.

FIG. 4B is a schematic cross-sectional view illustrating a cell control transistor of a semiconductor device according to an embodiment of the present disclosure.

FIG. 5A is a schematic cross-sectional view illustrating an example of a modified variable resistance element according to an embodiment of the present disclosure.

FIG. 5B is a schematic cross-sectional view illustrating an example of a modified variable resistance element according to another embodiment of the present disclosure.

FIG. 6 is a circuit diagram illustrating a forming operation of a semiconductor device according to an embodiment of the present disclosure.

FIG. 7A and FIG. 7B are schematic diagrams illustrating current flow at an initial stage of a forming operation according to an embodiment of the present disclosure.

FIG. 8A and FIG. 8B are schematic diagrams illustrating current flow at a later stage of a forming operation according to an embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or customs of a user or operator in the technical field. The meanings of the terms used follow the definitions defined when specifically defined herein, and may be interpreted as meanings generally recognized by those skilled in the art in the absence of specific definitions. It will also be understood that when an element is referred to as being “on,” “above,” “below,” or “under” another element, it can be directly “on,” “above,” “below,” or “under” the other element, respectively, or intervening elements may also be present. Accordingly, the terms such as “on,” “above,” “below,” or “under” are used for the purpose of describing particular embodiments only and are not intended to limit the inventive concept. It will be further understood that when an element is referred to as being “connected” or “electrically coupled” to another element, it can be directly connected or electrically coupled to the other element or intervening elements may be present.

In addition, when describing an operation method, each process constituting the operation method may be performed in a different order from the stated order unless a specific order is clearly stated in the context. That is, each process may be performed sequentially in the same order as the stated order or may be performed substantially simultaneously, and at least some processes may be performed in a different order.

In an embodiment, a semiconductor device may include a cell control transistor, a resistive memory cell, and a bit line that are coupled to one another. In some embodiments, a semiconductor device may include a cell control transistor and a plurality of resistive memory cells that share a bit line. In an aspect of an embodiment, the cell control transistor controls a forming operation of the resistive memory cell or forming operations of the plurality of resistive memory cells.

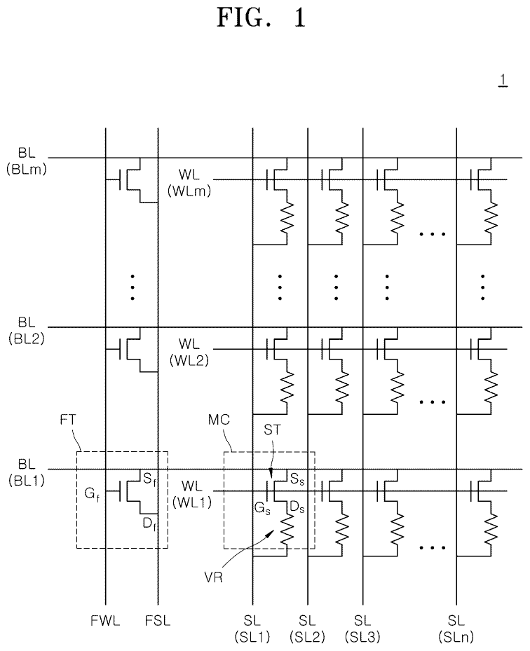

FIG. 1 is a circuit diagram of a semiconductor device according to an embodiment of the present disclosure. Referring to FIG. 1, a semiconductor device 1 includes arrays of resistive memory cells MCs and cell control transistors FTs.

Specifically, as shown in FIG. 1, the semiconductor device 1 includes “n” source lines SLs, that is, first to “n”^{th} source lines SL1, SL2, SL3, . . . , and SLn, “m” bit lines BLs, that is, first to “m”^{th} bit lines BL1, BL2, . . . , and BLm, and “m” cell word lines WLs, that is, first to “m”^{th} cell word lines WL1, WL2, . . . , and WLm. Each of the resistive memory cells MCs is connected to one source line SL, one bit line BL, and one word line WL that are selected from the “n” source lines SLs, “m” bit lines BLs, and “m” word lines WLs.

The semiconductor device 1 includes a single control word line FWL and a single control source line FSL. Each of the cell control transistors FTs is connected to the single control word line FWL and the single control source line FSL. In addition, each of the cell control transistors FTs is connected to one bit line BL selected from the “m” bit lines BLs.

Referring to FIG. 1, an “n” number of resistive memory cells MCs and one cell control transistor FT share one bit line BL. The “n” resistive memory cells MCs connected to the same bit line BL are also connected to the same cell word line WL. Each of the “m” bit lines BLs in the semiconductor device 1 is commonly connected to an “n” number of resistive memory cells MCs and one cell control transistor FT. Accordingly, the semiconductor device 1 includes “m×n” resistive memory cells MCs and “m” cell control transistors FTs.

Referring to FIG. 1, each of the plurality of resistive memory cells MCs includes a cell selection transistor ST and a variable resistance element VR. The cell selection transistor ST includes a cell gate electrode Gs electrically connected to a corresponding cell word line WL, a cell source electrode Ss electrically connected to a corresponding bit line BL, and a cell drain electrode Ds electrically connected to a corresponding source line SL via the variable resistance element VR. One end of the variable resistance element VR is electrically connected to the cell drain electrode Ds of the cell selection transistor ST, and the other end of the variable resistance element VR is electrically connected to a corresponding source line SL.

Each of the plurality of cell control transistors FTs includes a control gate electrode Gf electrically connected to the control word line FWL, a control source electrode Sf electrically connected to a corresponding bit line BL, and a control drain electrode Df electrically connected to the control source line FSL. As described, each of the cell control transistors FTs shares a bit line BL with “n” resistive memory cells MCs.

In an embodiment, the variable resistance element VR of the resistive memory cell MC may initially be an electrical insulator. When a forming operation is performed by applying a forming voltage to the variable resistance element VR, an electrical resistance of the variable resistance element VR may be reduced to a resistance state corresponding to a conductor. A set operation and a reset operation for writing signal information to the resistive memory cell MC is performed using a variable resistance element VR after the forming operation has been completed. As an example, the set operation may mean an operation of applying a set voltage to the variable resistance element VR on which the forming operation has been completed, thereby changing the electrical resistance of the variable resistance element VR into a low resistance state. As another example, the reset operation may mean an operation of applying a reset voltage to the variable resistance element VR on which the forming operation has been completed, thereby changing the electrical resistance of the variable resistance element VR into a high resistance state. The forming voltage may be greater than the set voltage and the reset voltage. In an embodiment, the forming voltage and the set voltage may have the same polarity. The reset voltage may have an opposite polarity to the forming voltage and the set voltage.

The resistance state changed by the set operation or the reset operation may be stored in the resistive memory cell MC as signal information. In some embodiments, when performing the set operation, the set voltage may be applied in various magnitudes to generate a plurality of different resistance states between a high and a low resistance state. Similarly, when performing the reset operation, by applying the reset voltage in various magnitudes, a plurality of different resistance states may be generated between a high and a low resistance state. A plurality of pieces of signal information may be stored using the plurality of resistance states resulting from set operations or reset operations.

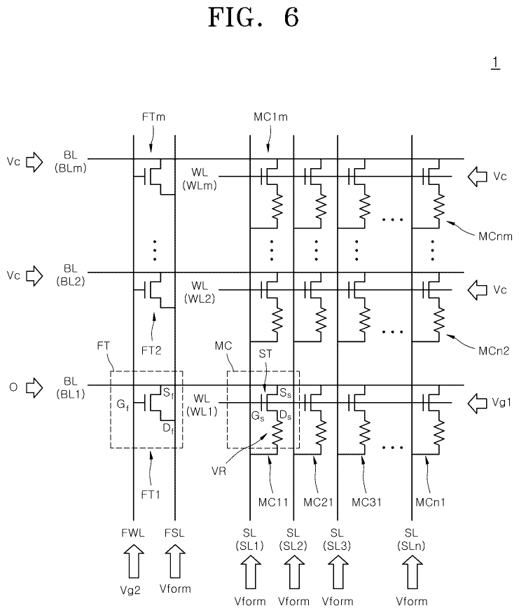

In an embodiment, the forming operation for a variable resistance element VR may be performed simultaneously on the plurality of memory cells MCs connected to the same bit line BL and the same cell word line WL. As described in detail below with reference to FIG. 6, the forming operations for the variable resistance elements VR of the plurality of memory cells MCs may be performed together by applying, respectively, a bit line operation potential and a cell word line operation potential to the bit line BL and the cell word line WL commonly connected to the plurality of memory cells MCs, and applying the same source line operation potential to the source lines SLs connected to the plurality of memory cells MCs.

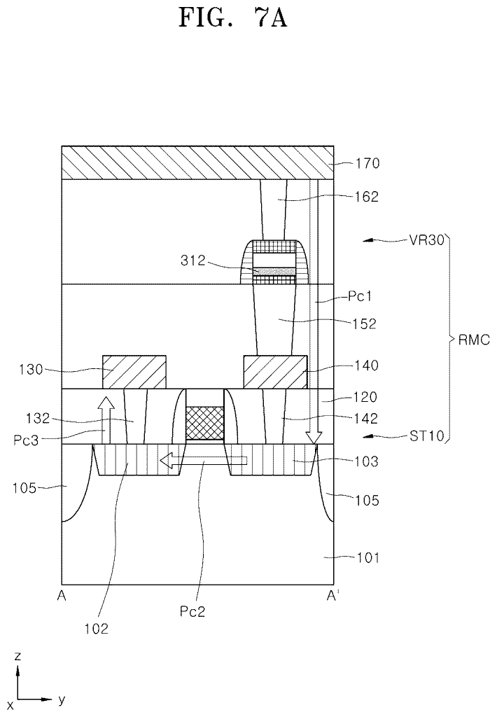

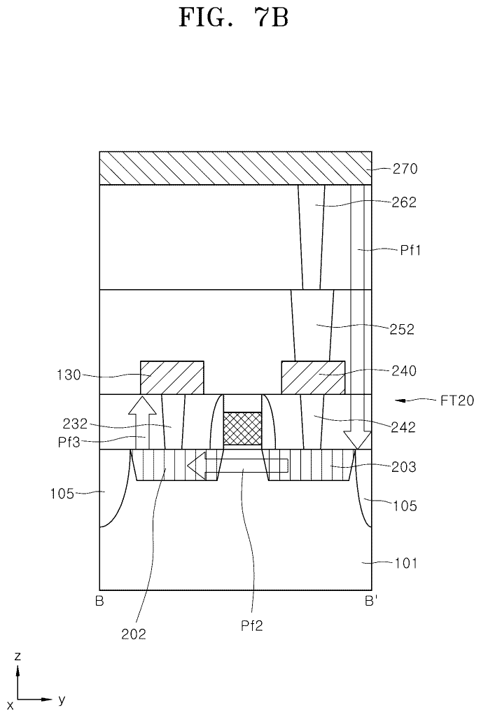

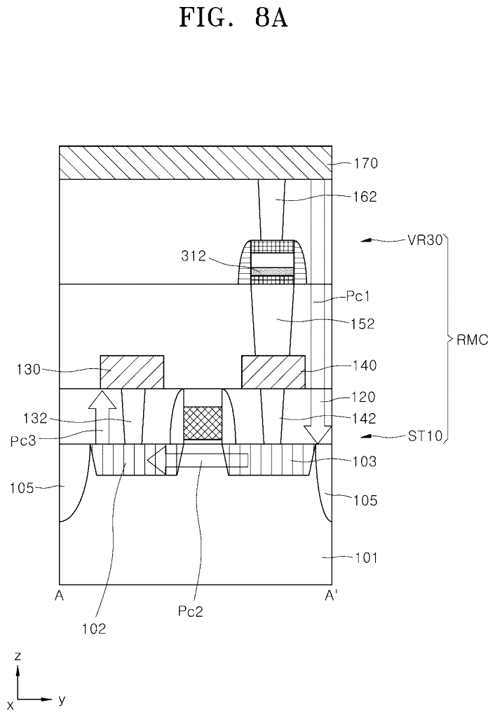

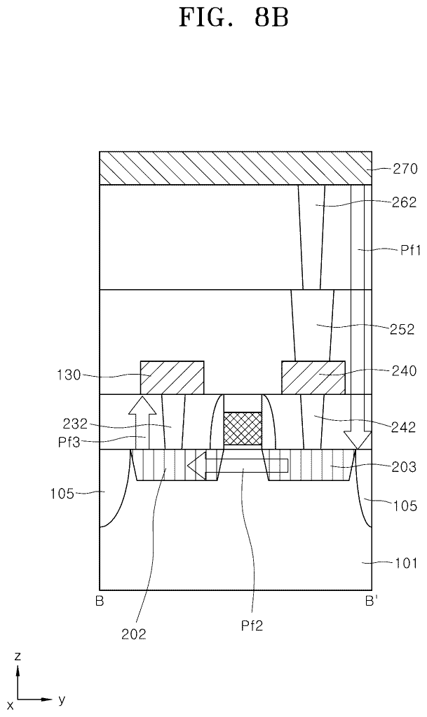

In an embodiment of the present disclosure, when a forming operation is performed on the variable resistance element VR of a target resistive memory cell MC, the cell selection transistor ST connected to the variable resistance element VR is turned on. Additionally, the cell control transistor FT sharing the bit line BL with the target resistive memory cell MC is turned on. The cell control transistor FT is turned on by the control word line potential applied to the control word line FWL. A control source line potential substantially the same as the source line potential applied to the target resistive memory cell MC and the source line SL is applied to the control source line FSL. In addition, the bit line operation potential of the bit line BL of the target resistive memory cell MC is applied to the bit line BL of the cell control transistor FT. As described below with reference to FIG. 6, FIG. 7A, FIG. 7B, FIG. 8A, and FIG. 8B, during the forming operation for the variable resistance element VR of the target resistive memory cell MC, the cell control transistor FT and the cell selection transistor ST may be configured to maintain a turn-on state from the initial stage of the forming operation through the latter stages of the forming operation until the forming operation is completed.

According to an embodiment of the present disclosure, the forming operation for the variable resistance element VR of the resistive memory cell MC may be performed when a cell control transistor FT in a turn-on state is sharing a bit line BL with the resistive memory cell MC. As described below with reference to FIG. 6, FIG. 7A, FIG. 7B, FIG. 8A, and FIG. 8B, according to an embodiment of the present disclosure, when resistance switching of the variable resistance element VR occurs during the forming operation, a peak operation current generated in the variable resistance element VR may be distributed from the resistive memory cell MC to the cell control transistor FT. That is, the cell control transistor FT can inhibit the peak operation current from damaging the resistive memory cell MC, and more specifically, from damaging the variable resistance element VR.

In FIG. 1, “m” bit lines BLs, “m” cell word lines WLs, and “n” source lines SLs are disclosed, but the present disclosure is not necessarily limited thereto, and in some embodiments, the number of bit lines BLs, the number of cell word lines WLs, and the number of source lines SLs may be variously modified.

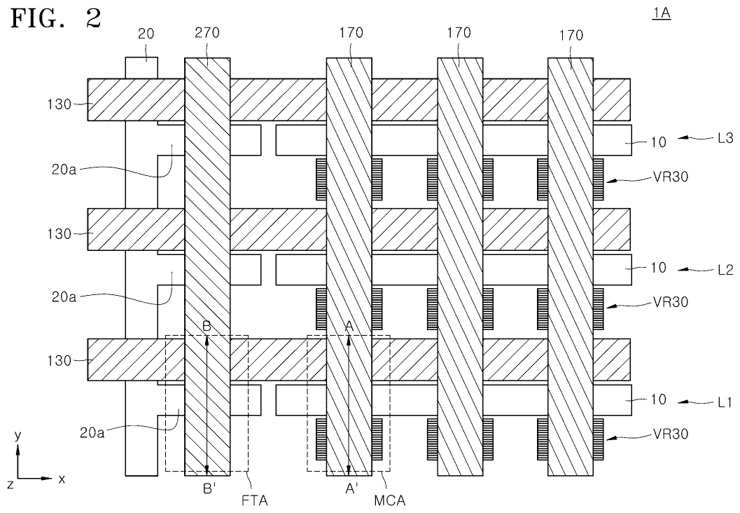

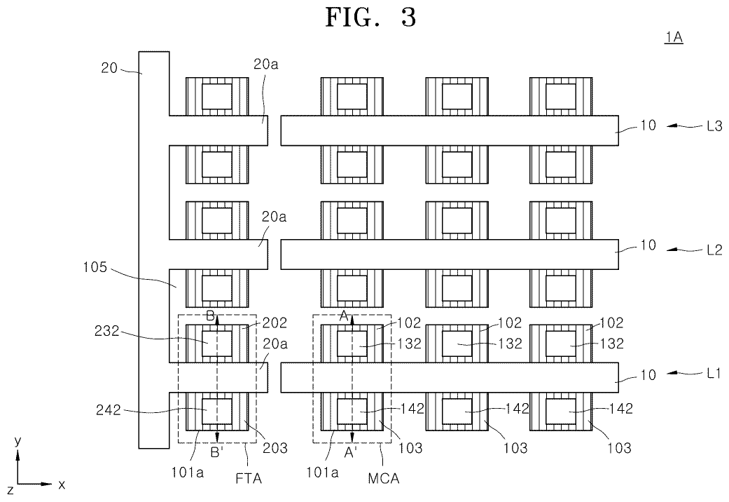

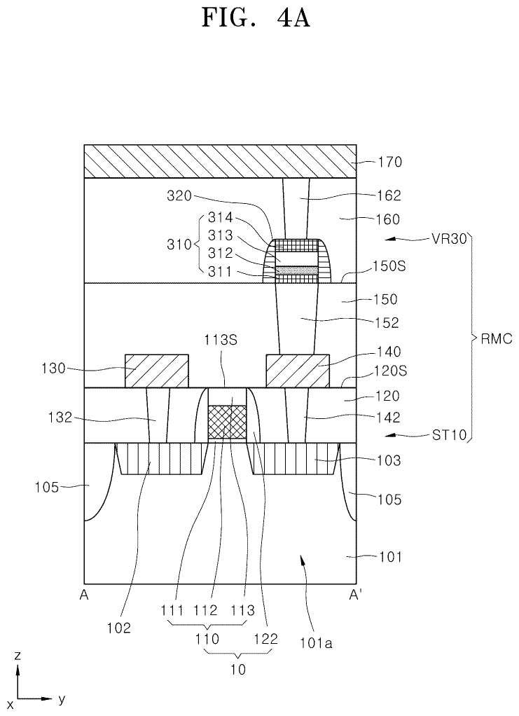

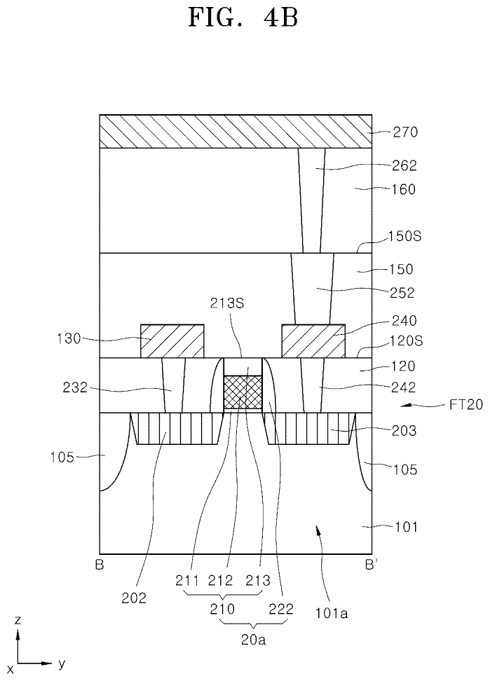

FIG. 2 is a schematic plan view illustrating a semiconductor device according to an embodiment of the present disclosure. FIG. 3 is a diagram illustrating a plan view of FIG. 2. In FIG. 3, a source line, a bit line, and a variable resistance element of FIG. 2 are omitted for the convenience of illustration. In FIG. 2 and FIG. 3, illustration of an interlayer insulation layer is omitted for the convenience of illustration. FIG. 4A is a schematic cross-sectional view illustrating a resistive memory cell of a semiconductor device according to an embodiment of the present disclosure. Specifically, FIG. 4A is a cross-sectional view of a resistive memory cell arrangement region MCA of FIG. 2 and FIG. 3 taken along a line A-A'. FIG. 4B is a schematic cross-sectional view illustrating a cell control transistor of a semiconductor device according to an embodiment of the present disclosure. Specifically, FIG. 4B is a cross-sectional view of a cell control transistor arrangement region FTA of FIG. 2 and FIG. 3 taken along a line B-B′. The semiconductor device 1A of FIG. 2, FIG. 3, FIG. 4A and FIG. 4B may be implemented in accordance with the circuit diagram of a semiconductor device 1 of FIG. 1.

Referring to FIG. 2, a semiconductor device 1A includes a plurality of cell word lines 10, a plurality of bit lines 130, and a plurality of source lines 170. The plurality of cell word lines 10 and the plurality of bit lines 130 are arranged along the y-direction, and the plurality of source lines 170 are arranged along the x-direction. The plurality of cell word lines 10 and the plurality of bit lines 130 extend in the x-direction and are disposed to parallel to each other. The plurality of source lines 170 extend in the y-direction and are disposed to overlap the plurality of cell word lines 10 and the plurality of bit lines 130 in the z-direction.

The semiconductor device 1A includes a plurality of variable resistance elements VR30 disposed between the plurality of cell word lines 10 and the plurality of bit lines 130. The plurality of variable resistance elements VR30 are disposed to be spaced apart from each other along the x-direction and the y-direction. The plurality of variable resistance elements VR30 overlap the plurality of source lines 170 in the z-direction.

Referring to FIG. 2, the semiconductor device 1A includes a control word line 20 that extends in the y-direction. The control word line 20 branches into a plurality of segments 20a. The plurality of segments 20a extend in the x-direction and are disposed parallel to each other. In an embodiment, the plurality of segments 20a are disposed parallel to the plurality of bit lines 130. In addition, the semiconductor device 1A includes a control source line 270 that extends in the y-direction and overlaps the plurality of bit lines 130 and the plurality of segments 20a in the z-direction.

Referring to FIG. 3, the plurality of cell word lines 10 are disposed to cross active regions 101a in the x-direction in resistive memory cell arrangement regions MCAs. Each of the active regions 101a may be a device region within a substrate 101, defined by a device isolation layer 105. In each of the active regions 101a common to resistive memory cell arrangement regions MCAs, a cell source region 102 and a cell drain region 103 are disposed at positions symmetrical to each other with respect to the cell word line 10. A first bit line contact 132 and a first connection pattern contact 142 are disposed within the cell source region 102 and the cell drain region 103, respectively. The first bit line contact 132 electrically connects the cell source region 102 to the bit line 130. The first connection pattern contact 142 is electrically connected to a connection pattern (i.e., component 140 of FIG. 4A) disposed between the cell drain region 103 and the variable resistance element VR30. In FIG. 3, the first bit line contact 132 and the first connection pattern contact 142 may have a rectangular planar shape, but are not necessarily limited thereto, and in some embodiments, may have a circular shape, an elliptical shape, or other various polygonal planar shapes.

Referring to FIG. 3, the segments 20a branching in the x-direction from the control word lines 20 are disposed across the active regions 101a in cell control transistor arrangement regions FTA. In each of the active regions 101a, a control source region 202 and a control drain region 203 are disposed at positions symmetrical to each other with respect to the segment 20a. A second bit line contact 232 and a second connection pattern contact 242 are disposed within the control source region 202 and the control drain region 203, respectively. The second bit line contact 232 electrically connects the control source region 202 to the bit line 130. The second connection pattern contact 242 is electrically connected to a connection pattern (i.e., component 240 of FIG. 4B) disposed between the control drain region 203 and the control source line 270. In FIG. 3, the second bit line contact 232 and the second connection pattern contact 242 may have a rectangular planar shape, but are not necessarily limited thereto, and in some embodiments, may have a circular shape, an elliptical shape, or other various polygonal planar shapes.

Referring to FIG. 2 and FIG. 3 together, a semiconductor device 1A includes one cell control transistor (component FT20 of FIG. 4B) and three resistive memory cells (component RMC of FIG. 4A), which share a bit line 130, in a first column L1. The three resistive memory cells RMC share a cell word line 10. Similarly, the semiconductor device 1A includes one cell control transistor FT20 and three resistive memory cells RMC, which share a bit line 130, in each of a second column L2 and a third column L3. Similarly, in each of the second column L2 and third column L3, the three resistive memory cells RMC share a cell word line 10. A configuration of the cell control transistor FT20 and the resistive memory cell RMC arranged over the substrate 101 is described in more detail below using FIG. 4A and FIG. 4B.

Referring to FIG. 2 and FIG. 3, in the semiconductor 1A, in each of the first column L1, the second column L2, and the third column L3, the three resistive memory cells RMC share the same cell control transistor FT20, but embodiments are not necessarily limited thereto. In other embodiments, a different number of resistive memory cells RMC sharing the same cell control transistor FT20 are disposed. In addition, in some embodiments, a semiconductor device may be provided in which the cell control transistors FT20 and the resistive memory cells RMC are arranged in a different number of columns other than three columns L1, L2, and L3 that each extend in the x-direction and are arranged to be parallel in the y-direction.

Referring to FIG. 2, FIG. 3, and FIG. 4A together, a resistive memory cell RMC includes a cell selection transistor ST10 and the variable resistance element VR30. The cell selection transistor ST10 is electrically connected to the bit line 130 and the cell word line 10, and electrically connected to the source line 170 through the variable resistance element VR30. The variable resistance element VR30 has various resistance states that are signal information of a resistive memory cell RMC.

The cell selection transistor ST10 includes a cell gate structure 110 disposed over the active region 101a of the substrate 101 and a cell gate spacer 122 disposed on a sidewall surface of the cell gate structure 110. The cell gate structure 110 and a cell gate spacer 122 are included in the cell word line 10.

The substrate 101 includes a semiconductor material on which a semiconductor integration process can be performed. The substrate 101 may be doped with an n-type or p-type dopant. In an embodiment, the substrate 101 may be a silicon (Si) substrate doped with a p-type dopant. The active region 101a may be a device region within the substrate 101, defined by the device isolation layer 105. The device isolation layer 105 constitutes an insulation region of the substrate 101, which is separated from the active regions 101a. The device isolation layer 105 includes, for example, oxide, nitride, oxynitride, or a combination of two or more thereof. The device isolation layer 105 may be formed by a shallow trench isolation (STI) process.

The cell gate structure 110 includes a cell gate dielectric layer 111 disposed on the substrate 101, a cell gate electrode layer 112 disposed on the cell gate dielectric layer 111, and a cell gate hard mask layer 113 disposed on the cell gate electrode layer 112. The cell gate dielectric layer 111 includes, for example, silicon oxide, silicon nitride, silicon oxynitride, aluminum oxide, hafnium oxide, zirconium oxide, or a combination of two or more thereof. The cell gate electrode layer 112 includes, for example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The cell gate spacer 122 is disposed on the substrate 101 and disposed to cover the sidewall surface of the cell gate structure 110. The cell gate spacer 122 includes, for example, silicon oxide, silicon nitride, silicon oxynitride, or a combination of two or more thereof.

Referring to FIG. 4A, the cell source region 102 that functions as a source electrode of the cell selection transistor ST10 is disposed in the active region 101a of the substrate 101 and located at one end of the cell gate structure 110. In addition, the cell drain region 103 that functions as a drain electrode of the cell selection transistor ST is disposed in the active region 101a of the substrate 101 and located at the other end of the cell gate structure 110. The cell source region 102 and the cell drain region 103 are doped with an n-type or p-type dopant. The doping type of the cell source region 102 and cell drain region 103 is different from the doping type of the substrate 101. For example, when the substrate 101 is doped with a p-type dopant, the cell source region 102 and the cell drain region 103 are doped with an n-type dopant.

Referring to FIG. 4A, a lower insulation layer 120 is disposed on the substrate 101 and disposed to bury the cell word line 10. The lower insulation layer 120 includes, for example, oxide, nitride, oxynitride, or a combination of two or more thereof. In an embodiment, an upper portion of the lower insulation layer 120 is planarized so that an upper surface 120S of the lower insulation layer 120 is located at the same level as an upper surface 113S of the cell gate hard mask layer 113.

The bit line 130 is disposed on the upper surface 120S of the lower insulation layer 120. As described with reference to FIG. 2, the bit line 130 extends in the x-direction. The bit line 130 includes a conductive material. The bit line 130 includes, for example, tungsten (W), copper (Cu), aluminum (Al), titanium (Ti), tungsten nitride, titanium nitride, or a combination of two or more thereof. The bit line 130 is electrically connected to the cell source region 102 by the first bit line contact 132 disposed in the lower insulation layer 120.

The first bit line contact 132 may be a conductive plug that extends through the lower insulation layer 120 from the cell source region 102 to the bit line 130. The first bit line contact 132 includes, for example, tungsten (W), copper (Cu), aluminum (Al), titanium (Ti), tungsten nitride, titanium nitride, or a combination of two or more thereof. As described with reference to FIG. 3, the first bit line contact 132 may have a planar cross-sectional shape of a circle, an ellipse, or a polygon.

Referring to FIG. 4A, the first connection pattern 140 is disposed on the upper surface 120S of the lower insulation layer 120 to be spaced apart from the bit line 130. The first connection pattern 140 includes a conductive material. The conductive material of the first connection pattern 140 may be substantially the same as the conductive material of the bit line 130. The first connection pattern 140 is electrically connected to the cell drain region 103 by the first connection pattern contact 142 disposed in the lower insulation layer 120. The first connection pattern contact 142 may be a conductive plug that extends through the lower insulation layer 120 from the cell drain region 103 to the first connection pattern 140. A configuration of the first connection pattern contact 142 may be substantially the same as a configuration of the first bit line contact 132.

Referring to FIG. 4A, an intermediate insulation layer 150 is disposed on the upper surface 120S of the lower insulation layer 120 to bury the bit line 130 and the first connection pattern 140. The intermediate insulation layer 150 includes, for example, oxide, nitride, oxynitride, or a combination of two or more thereof. A first lower via 152 is disposed within the intermediate insulation layer 150 to electrically connect the variable resistance element VR30 to the first connection pattern 140.

The variable resistance element VR30 is disposed on an upper surface 150S of the intermediate insulation layer 150. The variable resistance element VR30 includes a variable resistance structure 310 and a spacer insulation layer 320 disposed on the intermediate insulation layer 150 and on a sidewall surface of the variable resistance structure 310.

The variable resistance structure 310 includes a first electrode layer 311, a resistance change layer 312, an oxygen vacancy reservoir layer 313, and a second electrode layer 314 that are sequentially disposed on the upper surface 150S of the intermediate insulation layer 150.

The first electrode layer 311 includes a conductive material. The conductive material may include, for example, metal, conductive metal nitride, conductive metal carbide, conductive metal silicide, or conductive metal oxide. The conductive material may include, for example, platinum (Pt), gold (Au), tantalum (Ta), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide or, a combination of two or more thereof.

The resistance change layer 312 is disposed on the first electrode layer 311. The resistance change layer 312 includes a resistance change material whose electrical resistance changes depending on an applied voltage or applied current. In addition, the resistance change material may maintain, in a non-volatile manner, the changed electrical resistance after the applied voltage or applied current is removed.

In an embodiment, the resistance change layer 312 stores a plurality of resistance states by using different electrical resistance states as signal information. Electrical resistance may have a relationship in which a magnitude of the electrical resistance changes linearly depending on a magnitude of the applied operating voltage. The magnitude of the applied operating voltage may be controlled by, for example, an amplitude of direct current (DC) voltage, a width of a pulse voltage, or the number of times the pulse voltage is applied.

In an embodiment, the resistance change material of the resistance change layer 312 includes oxygen vacancies. During a forming operation or a set operation for the variable resistance element VR30, the oxygen vacancies are aggregated to form conductive filaments, which are electrical paths, within the resistance change layer 312. As a result, the electrical resistance of the resistance change layer 312 is decreased, and the resistance state is converted from a higher resistance state to a lower resistance state. Conversely, when a reset operation for the variable resistance element VR30 is performed, the oxygen vacancies within the conductive filament are decomposed, so that the electrical resistance of the resistance change layer 312 is increased, and the resistance state is converted from a lower resistance state to a higher resistance state.

The resistance change material includes metal oxide that does not satisfy a stoichiometric ratio. The resistance change material includes, for example, hafnium oxide, zirconium oxide, hafnium zirconium oxide, titanium oxide, aluminum oxide, or a combination of two or more thereof.

The oxygen vacancy reservoir layer 313 is disposed on the resistance change layer 312. The oxygen vacancy reservoir layer 313 provides oxygen vacancies to the resistance change layer 312 when a forming voltage or a set voltage is applied between the first electrode layer 311 and the second electrode layer 314. In addition, the oxygen vacancy reservoir layer 313 receives the oxygen vacancies from the resistance change layer 312 when a reset voltage is applied between the first electrode layer 311 and the second electrode layer 314. The polarity of the reset voltage may be opposite to the polarities of the forming voltage and the set voltage.

In an embodiment, the oxygen vacancy reservoir layer 313 includes metal having excellent reactivity with oxygen. The metal may include, for example, tantalum (Ta), titanium (Ti), zirconium (Zr), vanadium (V), tungsten (W), ruthenium (Ru), or a combination of two or more thereof.

The second electrode layer 314 is disposed on the oxygen vacancy reservoir layer 313. The second electrode layer 314 includes a conductive material. The second electrode layer 314 may include, for example, metal, conductive metal nitride, conductive metal carbide, conductive metal silicide, or conductive metal oxide.

In some embodiments, the oxygen vacancy reservoir layer 313 may be omitted from the variable resistance structure 310, and the second electrode layer 314 may also perform the role of the oxygen vacancy reservoir layer 313. Accordingly, the second electrode layer 314 may include metal that has reactivity with oxygen.

The spacer insulation layer 320 is disposed on the sidewall surface of the variable resistance structure 310. The spacer insulation layer 320 may perform the role of a barrier layer that suppresses material exchange and chemical reactions in a lateral direction (e.g., x-and y-directions) of the variable resistance structure 310.

Referring to FIG. 4A, an upper insulation layer 160 is disposed on the upper surface 150S of the intermediate insulation layer 150 and disposed to bury the variable resistance element VR30. The upper insulation layer 160 includes, for example, oxide, nitride, oxynitride, or a combination of two or more thereof.

The source line 170 is disposed on the upper insulation layer 160. As described with reference to FIG. 2, the source line 170 extends in the y-direction. The source line 170 includes a conductive material. The source line 170 includes, for example, tungsten (W), copper (Cu), aluminum (Al), titanium (Ti), tungsten nitride, titanium nitride, or a combination of two or more of thereof. The source line 170 is electrically connected to the variable resistance structure 310 by a first upper via 162 disposed within the upper insulation layer 160. The first upper via 162 may be a conductive plug that extends, in the z-direction, to the second electrode layer 314 of the variable resistance structure 310 from the source line 170. The first upper via 162 includes, for example, tungsten (W), copper (Cu), aluminum (Al), titanium (Ti), tungsten nitride, titanium nitride, or a combination of two or more thereof.

As described above, between a cell drain region 103 and a source line 170, a resistive memory cell RMC includes a first source line connection wiring electrically connecting cell drain region 103 with an end portion of variable resistance element VR30. From the end portion of variable resistance element VR30, a second source line connection wiring electrically connects the other end portion of the variable resistance element VR30 with the source line 170. The first source line connection wiring includes the first connection pattern contact 142, the first connection pattern 140, and the first lower via 152. The second source line connection wiring includes the first upper via 162.

Referring to FIG. 2, FIG. 3, FIG. 4A and FIG. 4B together, a cell control transistor FT20 is disposed spaced apart from the cell selection transistor ST10 on the substrate 101. Referring to FIG. 2, FIG. 3, and FIG. 4B together, the cell control transistor FT20 is electrically connected to the bit line 130, the control word line 20, and the control source line 270. As described with reference to FIG. 3, the cell control transistor FT20 shares a bit line 130 with three variable resistance elements VR30 disposed in the same column. The cell control transistor FT20 includes a control gate structure 210 that is a portion of the segment 20a branched from the control word line 20. In addition, the cell control transistor FT20 includes a control gate spacer 222 disposed on a sidewall surface of the control gate structure 210.

The control gate structure 210 includes a control gate dielectric layer 211 disposed on the substrate 101, a control gate electrode layer 212 disposed on the control gate dielectric layer 211, and a control gate hard mask layer 213 disposed on the control gate electrode layer 212. The control gate dielectric layer 211, the control gate dielectric layer 211 and the control gate hard mask layer 213 are disposed on the substrate 101 and disposed between the control source region 202 and the control drain region 203. The control gate dielectric layer 211, the control gate electrode layer 212, and the control gate hard mask layer 213 may have the same configurations of the cell gate dielectric layer 111, the cell gate electrode layer 112, and the cell gate hard mask layer 113 of the cell gate structure 110, respectively.

The control gate spacer 222 is disposed on the substrate 101 and disposed to cover the sidewall surface of the control gate structure 210. The control gate spacer 222 may have substantially the same configuration as the cell gate spacer 122 of the cell word line 10.

Referring to FIG. 4B, the control source region 202 that functions as a source electrode of the cell control transistor FT20 is disposed in the active region 101a of the substrate 101, and located at one end of the control gate structure 210. In addition, the control drain region 203 that functions as a drain electrode of the cell control transistor FT20 is disposed in the active region 101a of the substrate 101, and located at the other end of the control gate structure 210 in the y-direction. The control source region 202 and the control drain region 203 are doped with an n-type or p-type dopant. In an embodiment, when the substrate 101 is doped with a p-type dopant, the control source region 202 and the control drain region 203 are doped with an n-type dopant.

Referring to FIG. 4B, the lower insulation layer 120 buries the segment 20a of the control word line 20 disposed on the substrate 101 common to an arrangement region FTA of the cell control transistor. In an embodiment, an upper portion of the lower insulation layer 120 is planarized, so that an upper surface 120S of the lower insulation layer 120 is located at the same level as an upper surface 213S of the control gate hard mask layer 213.

The bit line 130 is disposed on the upper surface 120S of the lower insulation layer 120. As described with reference to FIG. 2, the bit line 130 extends in the x-direction. The bit line 130 is electrically connected to the control source region 202 by the second bit line contact 232 disposed inside the lower insulation layer 120. The second bit line contact 232 may have substantially the same configuration as the first bit line contact 132 described above with reference to FIG. 4A.

Referring to FIG. 4B, a second connection pattern 240 is disposed on the upper surface 120S of the lower insulation layer 120 to be spaced apart from the bit line 130. A configuration of the second connection pattern 240 may be substantially the same as a configuration of the first connection pattern 140 described above with reference to FIG. 4A. The second connection pattern 240 is electrically connected to the control drain region 203 by a second connection pattern contact 242 disposed within the lower insulation layer 120. The second connection pattern contact 242 may be a conductive plug that extends to contact the control drain region 203 from the second connection pattern 240. A configuration of the second connection pattern contact 242 may be substantially the same as a configuration of the first connection pattern contact 142 of FIG. 4A.

Referring to FIG. 4B, the bit line 130 and the second connection pattern 240 on the upper surface 120S of the lower insulation layer 120 are buried in the intermediate insulation layer 150. A second lower via 252 extending upward, that is, in the z-direction from the second connection pattern 240 is disposed inside the intermediate insulation layer 150.

The upper insulation layer 160 is disposed on the upper surface 150S of the intermediate insulation layer 150. The control source line 270 is disposed on the upper insulation layer 160. As described with reference to FIG. 2, the control source line 270 extends in the y-direction. In an embodiment, the control source line 270 is disposed to be parallel to the source line 170. A configuration of the control source line 270 may be substantially the same as the configuration of the source line 170. The control source line 270 is electrically connected to the second lower via 252 by a second upper via 262 disposed within the upper insulation layer 160. The second upper via 262 includes, for example, tungsten (W), copper (Cu), aluminum (Al), titanium (Ti), tungsten nitride, titanium nitride, or a combination of two or more thereof.

As described above, the cell control transistor FT20 includes a control source line connection wiring that electrically connects the control drain region 203 and the control source line 270. The control source line connection wiring includes the second connection pattern contact 242, the second connection pattern 240, the second lower via 252, and the second upper via 262.

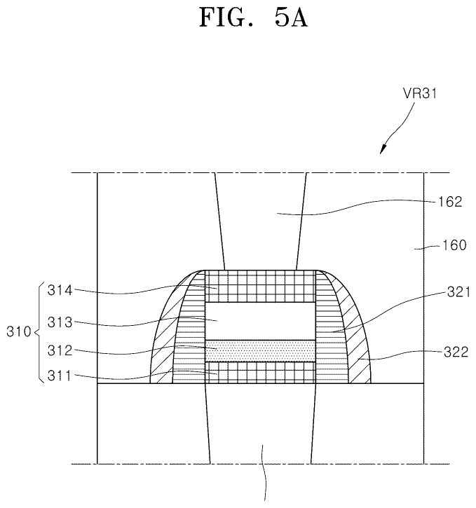

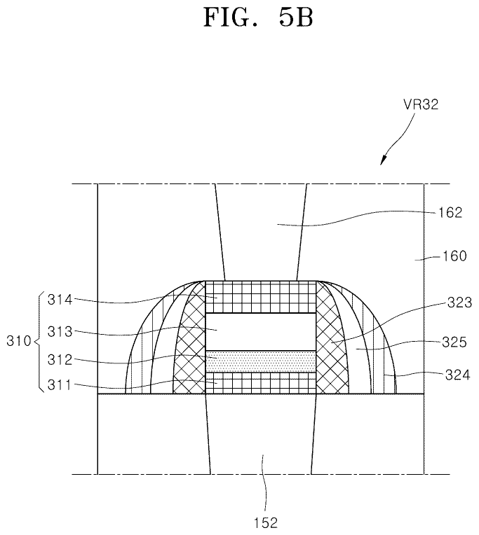

FIG. 5A is a schematic cross-sectional view illustrating an example of a modified variable resistance element according to an embodiment of the present disclosure. FIG. 5B is a schematic cross-sectional view illustrating an example of a modified variable resistance element according to another embodiment of the present disclosure.

Referring to FIG. 5A, a variable resistance element VR31 includes a first electrode layer 311, a resistance change layer 312, an oxygen vacancy reservoir layer 313, and a second electrode layer 314 that are sequentially disposed on a first lower via 152, a capping insulation layer 321 disposed along a sidewall surface of a variable resistance structure 310, and a heat insulation layer 322 disposed to cover the capping insulation layer 321. The capping insulation layer 321 serves as a barrier layer that suppresses material exchange and chemical reactions in a lateral direction of the variable resistance structure 310. The capping insulation layer 321 includes, for example, silicon oxide, silicon nitride, or silicon oxynitride.

The heat insulation layer 322 inhibits heat inside the variable resistance structure 310 from being released through the sidewall surface of the variable resistance structure 310. Specifically, the heat insulation layer 322 helps the variable resistance structure 310 retain the heat generated in a forming operation of the variable resistance element VR31. The retained heat promotes the formation of a conductive path within the resistance change layer 312 to improve the forming operation characteristics of the variable resistance element VR31. That is, when utilizing the heat insulation layer 322, a forming operation in the variable resistance element VR31 can be performed at a relatively lower forming voltage than when a heat insulation layer 322 is not provided. When the required forming voltage decreases, an operation current generated by the forming operation decreases in proportion to the decrease in the forming voltage. Accordingly, as described below with reference to FIG. 6, FIG. 7A, and FIG. 7B, when resistance switching of the variable resistance element VR31 occurs during the forming operation, the level of a peak operation current generated from the variable resistance element VR31 in advance can be lowered. Accordingly, it is possible to inhibit a resistive memory cell (RMC) from being damaged by a higher peak operation current at the beginning of the forming operation.

The heat insulation layer 322 includes a dielectric material having low thermal conductivity. The heat insulation layer 322 includes, for example, an oxide dielectric material or an organic dielectric material. Specifically, the heat insulation layer 322 may include fluorine-doped silicon oxide, carbon-doped silicon oxide, a metal-organic framework, or the like. The heat insulation layer 322 may have a porous structure. The heat insulation layer 322 may have electrically insulating characteristics.

Referring to FIG. 5B, a variable resistance element VR32 includes a first electrode layer 311, a resistance change layer 312, an oxygen vacancy reservoir layer 313, and a second electrode layer 314 that are sequentially disposed on a first lower via 152, and a first capping insulation layer 323 and a second capping insulation layer 324 that are sequentially disposed along a sidewall surface of a variable resistance structure 310 over the substrate 101. In addition, the variable resistance element VR32 includes an insulation air gap 325 located between the first capping insulation layer 323 and the second capping insulation layer 324 in a lateral direction. The insulation air gap 325 is an empty space between the first capping insulation layer 323 and the second capping insulation layer 324 where no material layer exists. The empty space may be filled with air or gas. Because air or gas has heat insulating properties, the insulation air gap 325 functions as heat insulation. The configurations of the first and second capping insulation layers 323 and 324 may be substantially the same as the configuration of the capping insulation layer 321 of FIG. 5A.

FIG. 6 is a circuit diagram illustrating a forming operation of a semiconductor device according to an embodiment of the present disclosure. FIG. 7A and FIG. 7B are schematic diagrams illustrating current flow at an initial stage of a forming operation according to an embodiment of the present disclosure. In addition, FIG. 8A and FIG. 8B are schematic diagrams illustrating current flow at a later stage of a forming operation according to an embodiment of the present disclosure. The schematic diagrams of FIGS. 7A and 7B and the schematic diagrams of FIGS. 8A and 8B are based on the forming operation of the same semiconductor device from an illustrative embodiment of the present disclosure.

In an embodiment, the forming operation proceeds through an initial stage of the forming operation and a later stage of the forming operation. The initial stage of the forming operation means a time period before an electrical resistance of the variable resistance element is switched from a high resistance state to a low resistance state after a forming voltage is applied. The later stage of the forming operation means a time period after the electrical resistance of the variable resistance element has been switched from the high resistance state to the low resistance state after the forming voltage is applied.

The circuit diagram of FIG. 6 corresponds to the circuit diagram of the semiconductor device 1 of FIG. 1, the cross-sectional views of FIG. 7A and FIG. 8A correspond to the cross-sectional views of the arrangement region MCA of the resistive memory cell illustrated in FIG. 4A, and the cross-sectional views of FIG. 7B and FIG. 8B correspond to the cross-sectional views of the arrangement region FTA of the cell control transistor illustrated in FIG. 4B.

Referring to FIG. 6, a semiconductor device 1 includes “m ×n” resistive memory cells MC11, MC21, MC31, . . . , and MCmn. Among the resistive memory cells MC11, MC21, MC31, . . . , and MCmn, a forming operation for the first to “n”^{th} resistive memory cells MC11, MC21, MC31, . . . , and MCn1 located in a lowest row will be described as an example. For the forming operation, a first bit line BL1 is selected from among first to “m”^{th} bit lines BL1, BL2, . . . , and BLm. A ground potential, that is, 0 V is applied to the selected first bit line BL1, and an inactive potential Vc having a positive polarity is applied to unselected second to “m”^{th} bit lines BL2, . . . , and BLm.

A forming operation potential Vform having a positive polarity is applied to each of first to “n”^{th} source lines SL1, SL2, SL3, . . . , and SLn. In addition, the same forming operation potential Vform is applied to a first control source line FSL.

The first cell word line WL1 to which the first to “n”^{th} resistive memory cells MC11, MC21, MC31, . . . , and MCn1 are electrically connected, from among first to “m” ^{h} cell word lines WL1, WL2, . . . , and WLm, is selected. A cell word line operation potential Vg1 having a positive polarity is applied to the selected first cell word line WL1. The inactive potential Vc is applied to the unselected second to “m”^{th} cell word lines WL2, . . . , and WLm.

A cell gate voltage corresponding to a difference between the cell word line operating potential Vg1 of the first cell word line WL1 and the ground potential of the first bit line BL1 is applied to a cell selection transistor ST. That is, when the ground potential is 0 V of the first bit line BL1, the cell gate voltage is Vg1. Because the cell gate voltage is greater than a threshold voltage Vth-s of the cell selection transistor ST, the cell selection transistor ST connected to the first cell word line WL1 is turned on. In the cell selection transistors ST connected to the unselected second to “m”^{th} cell word lines WL2, . . . , and WLm and the unselected second to “m”^{th} bit lines BL2, . . . , and BLm, the turn-off state is maintained because the cell gate voltage is not generated.

Meanwhile, a control word line operation potential Vg2 is applied to a control word line FWL. A control gate voltage corresponding to a difference between the control word line operation potential Vg2 of the control word line FWL and the ground potential of the first bit line BL1 may be applied to the first cell control transistor FT1. That is, when the ground potential is 0 V of the first bit line BL1, the cell gate voltage is Vg2. Because the control gate voltage is greater than a threshold voltage Vth-f of a first cell control transistor FT1, the first cell control transistor FT1 is turned on. For unselected second to “m”^{th} cell control transistors FT2, . . . , and FTm, a control gate voltage corresponding to a difference between the control word line operation potential Vg1 and the inactive potential Vc of the second to “m”^{th} bit lines BL2, . . . , and BLm, that is, Vg2-Vc is smaller than the threshold voltage Vth-f of each of the second to “m”^{th} cell control transistors FT2, . . . , and FTm, so that the second to “m”^{th} cell control transistors FT2, . . . , and FTm are maintained in a turn-off state.

As described above, after the cell selection transistor ST and the first cell control transistor FT1 of each of the first to “n”^{th} resistive memory cells MC11, MC21, MC31, . . . , and MCn1 are turned on, a forming voltage is applied to each of the first to “n”^{th} resistive memory cells MC11, MC21, MC31, . . . , and MCn1 and the first cell control transistor FT1. The forming voltage may correspond to a difference between the forming operation potential Vform of the first to “n”^{th} source lines SL1, SL2, SL3, . . . , and SLn and the ground potential of the first bit line BL1. That is, when. That is, when ground potential is 0 V of the first bit line BL1, the forming voltage is Vform. In addition, the forming voltage may correspond to a difference between the forming operation potential Vform of a control source line FSL and the ground potential of the first bit line BL. When the ground potential is 0V of the first bit line BL, the forming voltage is Vform. In this way, during the forming operation for the variable resistance element VR of each of the first to “n”^{th} resistive memory cells MC11, MC21, MC31, . . . , and MCn1, the voltage applied between the first to “n”^{th} source lines SL1, SL2, SL3, . . . , and SLn and the first bit line BL1 may be configured to be substantially equal to the voltage applied between the control source line FSL and the first bit line BL1. The forming voltage may be configured to be maintained throughout the initial stage and the later stage of the forming operation.

Referring to FIG. 6, because the first cell control transistor FT1 and the first to “n”^{th} resistive memory cell MC11, MC21, MC31, . . . , and MCn1 share the first bit line BL1, the operation current generated by applying the forming voltage is distributed and flows to each of the first cell control transistor FT1 and the first to “n”^{th} resistive memory cells MC11, MC21, MC31, . . . , and MCn1.

According to an embodiment, at the initial stage of the forming operation, the switching operation in which the electrical resistance of the variable resistance element VR of each of the first to “n”^{th} resistive memory cells MC11, MC21, MC31, . . . , and MCn1 is converted from a high resistance state to a low resistance state might not be completed. Therefore, at the initial stage of the forming operation, the operation currents are generated by the forming voltage. Portions of the currents flowing through the interior of the first cell control transistor FT1, which is a relatively low-resistance path, are greater than portions of the currents flowing through the variable resistance element VR, which is a high-resistance path. At the initial stage of the forming operation, the variable resistance element VR having a high resistance state contributes to the high-resistance path. The specific flow of the operation current generated at the initial stage of the forming operation is described in more detail through FIG. 7A and FIG. 7B.

Referring to FIG. 7A, current paths and current magnitudes of the currents flowing through the resistive memory cell RMC are shown by arrows when the variable resistance element VR still remains in a high resistance state immediately after the cell selection transistor ST of one of the first to “n”^{th} resistive memory cells MC11, MC21, MC31, . . . , and MCn1 is turned on. The operation current flowing through the resistive memory cell RMC has a first cell path Pc1 between the source line 170 and the cell drain region 103, a second cell path Pc2 passing through a channel of the cell selection transistor ST10, and a third cell path Pc3 between the cell source region 102 and the bit line 130. Referring to FIG. 7B, in the initial stage of the forming operation, the operation current flowing through the cell control transistor FT20 includes a first control path Pf1 between the control source line 270 and the control drain region 203, a second control path Pf2 passing through a channel of the cell control transistor FT20, and a third control path Pf3 between the control source region 202 and the bit line 130.

In the initial stage of the forming operation, because the resistance change layer of a variable resistance element VR30 is an electrical insulator, the electrical resistance of the first cell path Pc1 of the resistive memory cell RMC may be greater than the electrical resistance of the first control path Pf1 of the cell control transistor FT20. As an example, the electrical resistance of the first cell path Pc1 may be at least five times greater than the electrical resistance of the first control path Pf1. As another example, the electrical resistance of the first cell path Pc1 may be at least ten times greater than the electrical resistance of the first control path Pf1. Meanwhile, the electrical resistances of the second and third cell paths Pc2 and Pc3 of the resistive memory cell RMC may be substantially equal to the electrical resistances of the second and third control paths Pf2 and Pf3 of the cell control transistor FT20. As a result, at the beginning of the forming operation, a portion of the operation current distributed to the cell control transistor FT20 may be greater than the portion of the operation current distributed to the resistive memory cell RMC. Widths of the arrows illustrating the magnitudes of the currents through Pc1, Pc2 and Pc3 as shown in FIG. 7A are smaller than widths of the arrows illustrating the magnitudes of the currents through Pf1, Pf2 and Pf3 as shown in FIG. 7B, respectively.

Referring to FIG. 6 again, as the forming operation progresses, the electrical resistance of the variable resistance element VR is switched from a high resistance state to a low resistance state. Accordingly, the electrical resistance of the variable resistance element VR is decreased. At a moment when the resistance switching to the low resistance state occurs, the operation current passing through the variable resistance element VR rapidly increases instantaneously. The instantaneous rapid increase in operation current decreases over time to a stable level, so the instantaneously and rapidly increased operation current may be observed as a peak-shaped current. In the present specification, the instantaneously rapidly increased operation current is referred to as a “peak operation current”.

Unlike the disclosed embodiments, when there is no cell control transistor FT, the peak operation current may electrically and structurally damage the variable resistance element VR. As an example, conductive layers and insulation layers located on or over the first cell path Pc1 of FIG. 7B may be relatively significantly damaged due to the peak operation current.

According to an embodiment of the present disclosure, when a peak operation current occurs in resistive memory cells RMC, the peak operation current can be distributed or may flow to the cell control transistor FT using the resistance switching of the variable resistance element VR. As a result, the resistive memory cells RMC can be inhibited from being damaged by the peak operation current.

FIG. 8A and FIG. 8B are schematic diagrams illustrating current flow at a later stage of a forming operation according to an embodiment of the present disclosure. An operation current flowing through a resistive memory cell RMC and a cell control transistor FT after the resistance switching of a variable resistance element VR is completed during the forming operation may have substantially the same magnitude through the resistive memory cell RMC and the cell control transistor FT. Widths of the arrows illustrating the magnitudes of the currents through Pc1, Pc2 and Pc3 as shown in FIG. 8A are the same as width of the arrows illustrating the magnitudes of the currents through Pf1, Pf2 and Pf3 as shown in FIG. 8B, respectively.

According to an embodiment of the present disclosure, after the forming operation is completed, a set operation for storing signal information in units of resistive memory cells may be performed. Referring to FIG. 1, the set operation is performed by applying a bit line set potential, a cell word line operation potential, and a source line set potential to a bit line BL, a cell word line WL, and a source line SL that are connected to a target resistive memory cell MC, respectively. In FIG. 8A and FIG. 8B, a cell control transistor FT that shares the bit line BL with the target resistive memory cell MC is turned off.

Accordingly, the selection transistor ST of the target resistive memory cell MC is turned on, and a set voltage corresponding to a difference between the source line set potential and the bit line set potential is applied to the variable resistance element VR30. The set voltage can switch the electrical resistance of the variable resistance element VR from a high resistance state to a low resistance state.

In some embodiments, by applying the set voltage with various voltage magnitudes, set operations can result in variable resistance elements VR having multiple possible different resistance states. Accordingly, the resistive memory cell MC can store multiple pieces of signal information using the multiple resistance states.

According to an embodiment of the present disclosure, after the forming operation is completed, a reset operation may be performed to erase the signal information stored in a single resistive memory cell or the plurality of resistive memory cells. Referring to FIG. 1, the reset operation is performed by applying a bit line reset potential, a cell word line operation potential, and a source line reset potential to a bit line BL, a cell word line WL, and a source line SL connected to at least one target resistive memory cell MC, respectively. In this case, the cell control transistor FT sharing the bit line BL with the target resistive memory cell MC may be turned off.

Accordingly, the selection transistor ST of the target resistive memory cell MC is turned on, and a reset voltage corresponding to the difference between the source line reset potential and the bit line reset potential is applied to the variable resistance element VR. The reset voltage has a polarity opposite to that of the set voltage. The reset voltage may switch the electrical resistance of the variable resistance element VR from a low resistance state to a high resistance state.

In some embodiments, by applying reset voltages with various voltage magnitudes, reset operations can result in variable resistance elements VR having multiple possible different resistance states. Accordingly, the resistive memory cell MC can store multiple pieces of signal information using the multiple resistance states.

In some embodiments, the semiconductor device 1 of FIG. 1 may be applied to an analog computing in memory (AciM) device. Through the set operation or the reset operation, each of the plurality of resistive memory cells MC in the semiconductor device 1 can store a plurality of resistance states as weights.

According to an embodiment, in a state where a target bit line BL is selected and a cell selection transistor SL commonly connected to the bit lines BL is turned on, voltage signals may be input through the multiple source lines SL1, SL2, SL3, . . . , and SLn. A multiplication and accumulation (hereinafter, referred to as “MAC”) operation is performed on the weights stored in each resistive memory cell MC by the voltage signal, and a result of the performed multiplication and accumulation (MAC) operation may be output as a current signal through the target bit line BL. While the MAC operation is performed, the cell control transistor FT may be turned off.

In some embodiments, voltage signals may be input through the plurality of bit lines BL1, BL2, . . . , and BLn while a target source line SL is selected and a cell selection transistor SL connected to the target source line SL is turned on. A multiplication and accumulation (MAC) operation is performed on the weights stored in the resistive memory cells MCs by the voltage signal, and a result of the performed multiplication and accumulation operation may be output as a current signal through the target source line SL. While the MAC operation is performed, the cell control transistor FT may be turned off.

As described above, semiconductor devices according to embodiments of the present disclosure can function as an analog computing in memory (AciM) devices in which MAC operation are performed.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered from a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A semiconductor device comprising:
a cell control transistor, a resistive memory cell, and a bit line that are disposed on a substrate and coupled to one another,
wherein the resistive memory cell comprises:
a cell selection transistor disposed to be spaced apart from the cell control transistor on the substrate; and
a variable resistance element electrically connected to a drain electrode of the cell selection transistor, and
wherein a source electrode of the cell control transistor and a source electrode of the cell selection transistor are electrically connected to the bit line in common.

2. The semiconductor device of claim 1, wherein the cell control transistor comprises:
a control gate structure including a control gate dielectric layer and a control gate electrode layer that are sequentially disposed on the substrate;
a control source region disposed at an end of the control gate structure as the source electrode in an active region of the substrate; and
a control drain region disposed at the other end of the control gate structure as the drain electrode in the active region of the substrate.

3. The semiconductor device of claim 2, wherein the cell control transistor further comprises:
a control source line disposed over the substrate; and
a source line connection wiring on the substrate, electrically connecting the control drain region and the control source line.

4. The semiconductor device of claim 1, wherein the cell selection transistor comprises:
a cell gate structure including a cell gate dielectric layer and a cell gate electrode layer that are sequentially disposed on the substrate;
a cell source region located at an end of the cell gate structure and is the source electrode in an active region of the substrate; and
a cell drain region located at the other end of the cell gate structure and is the drain electrode in the active region of the substrate.

5. The semiconductor device of claim 4, wherein further comprises:
a source line disposed over the substrate;
a first source line connection wiring that electrically connects the cell drain region with an end portion of the variable resistance element; and
a second source line connection wiring that electrically connects another end portion opposite to the end portion of the variable resistance element with the source line.

6. The semiconductor device of claim 1, wherein the cell control transistor and the cell selection transistor are configured to maintain a turn-on state during a forming operation for the variable resistance element of the resistive memory cell.

7. The semiconductor device of claim 1, further comprising:
a control source line electrically connected to a drain electrode of the cell control transistor; and
a source line electrically connected to an end portion of the variable resistance element,
wherein a voltage applied between the bit line and the control source line is substantially equal to a voltage applied between the bit line and the source line during a forming operation for the variable resistance element of the resistive memory cell.

8. The semiconductor device of claim 1, wherein the variable resistance element comprises a variable resistance structure including a first electrode layer, a resistance change layer, an oxygen vacancy reservoir layer, and a second electrode layer that are sequentially disposed over the substrate.

9. The semiconductor device of claim 8, wherein the variable resistance element further comprises a heat insulation layer disposed along a sidewall surface of the variable resistance structure.

10. The semiconductor device of claim 8, wherein the variable resistance element further comprises:
a first capping insulation layer and a second capping insulation layer that are sequentially disposed along a sidewall surface of the variable resistance structure over the substrate; and
an insulation air gap located between the first capping insulation layer and the second capping insulation layer.

11. A semiconductor device comprising:
a cell control transistor and a plurality of resistive memory cells that share a bit line;
wherein the cell control transistor comprises a control source region and a control drain region that are disposed in a substrate, and a control gate electrode layer disposed on the substrate between the control source region and the control drain region,
wherein each of the plurality of resistive memory cells comprises:
a cell selection transistor including a cell source region and a cell drain region that are disposed in the substrate, and a cell gate electrode layer disposed on the substrate between the cell source region and the cell drain region; and
a variable resistance structure electrically connected to the cell drain region of the cell selection transistor, and
wherein the control source region and the cell source region are electrically connected to the bit line in common.

12. The semiconductor device of claim 11, further comprising:
a control word line electrically connected to the control gate electrode layer of the cell control transistor; and
a cell word line electrically connected to the cell gate electrode layer of the plurality of resistive memory cells in common.

13. The semiconductor device of claim 11, further comprising:
a control source line disposed over the substrate; and
a control source line connection wiring that electrically connects the control drain region with the control source line.

14. The semiconductor device of claim 13,
further comprising a plurality of source lines disposed over the substrate,
wherein each of the plurality of resistive memory cells comprises:
a first source line connection wiring that electrically connects the cell drain region with an end portion of the variable resistance structure; and
a second source line connection wiring that electrically connects the opposite end portion of the variable resistance structure with a corresponding source line.

15. The semiconductor device of claim 14, wherein the cell control transistor and the cell selection transistor of the plurality of resistive memory cells are configured to maintain a turn-on state during a forming operation for the plurality of resistive memory cells.

16. The semiconductor device of claim 15, wherein a voltage applied between the bit line and the control source line is substantially equal to a voltage applied between the bit line and the plurality of the source lines during the forming operation for the plurality of resistive memory cells.

17. The semiconductor device of claim 11, wherein the variable resistance structure comprises a first electrode layer, a resistance change layer, an oxygen vacancy reservoir layer, and a second electrode layer that are sequentially disposed over the substrate.

18. The semiconductor device of claim 11, wherein each of the plurality of resistive memory cells further comprises a heat insulation layer disposed along a sidewall surface of the variable resistance structure over the substrate.

19. The semiconductor device of claim 11, wherein each of the plurality of resistive memory cells comprises:
a first capping insulation layer and a second capping insulation layer that are sequentially disposed along a sidewall surface of the variable resistance structure over the substrate; and
an insulation air gap located between the first capping insulation layer and the second capping insulation layer.

20. The semiconductor device of claim 11,
wherein the cell control transistor and the cell selection transistor of the plurality of resistive memory cells share the bit line, and
wherein the cell gate electrode layer of the plurality of resistive memory cells shares a cell word line.
